(19) United States
(12) Patent Application Publication
(10) Pub. No.: US 2003/0116350 A1
(43) Pub. Date: Jun. 26, 2003

(54) Flexible wiring boards and manufacturing processes thereof

(75) Inventor: Yutaka Kaneda, Kanuma-shi (JP)

Correspondence Address: OLIFF & BERRIDGE, PLC, P.O. BOX 19928, ALEXANDRIA, VA, 22320, US

(73) Assignee: SONY CHEMICALS CORP., Tokyo (JP)

(21) Appl. No.: 10/023,651

(22) Filed: Dec. 21, 2001

(30) Foreign Application Priority Data
Dec. 21, 2001 (JP) 2000-388499

(51) Int. Cl. H05K 1/11; H01R 12/04

(52) U.S. Cl. 174/261

(57) ABSTRACT

A process for manufacturing a flexible wiring board with easy handling at reduced production costs comprises the steps of forming a first wiring pattern and a guide pattern around the outer periphery of the first wiring pattern on a copper foil, and forming an insulating film on the first wiring pattern and guide pattern.

### FIELD OF THE INVENTION

The present invention relates to processes for manufacturing flexible wiring boards used for electrically connecting electronic components, for example, particularly to the technique of reinforcing flexible wiring boards.

### BACK GROUND OF RELATED ART

Flexible wiring boards comprising a high-density wiring pattern formed of a layer of a conductor such as copper foil laminated on a flexible insulating film to electrically connect wiring boards have been known.

However, conventional flexible wiring boards are formed in a very small thickness almost equal to that of the copper foil of the wiring pattern, so that a rigid reinforcing guide frame must be bonded to the flexible wiring boards from the viewpoint of handling when they are used as interposers such as CSP (chop size package), for example, which leads to the problem of high costs.

The present invention was made to overcome the disadvantages of the prior art described above with the purpose of providing a process for manufacturing a flexible wiring board with easy handling at reduced production costs.

### SUMMARY OF THE INVENTION

The present invention provides a process for manufacturing a flexible wiring board comprising forming a wiring pattern and a reinforcing guide pattern by etching a metal foil on an insulating substrate.

The present invention also provides a flexible wiring board comprising a wiring pattern formed of a desired metal on a film-like insulating substrate wherein a reinforcing guide pattern having the same material as that of the wiring pattern is formed on the insulating substrate.

In the flexible wiring board of the present invention, the guide pattern ha a projecting reinforcing guide having a thickness greater than that of the wiring pattern.

In the flexible wiring board of the present invention, the guide pattern may be formed as a frame shape surrounding the periphery of the wiring pattern.

In the flexible wiring board of the present invention, the wiring pattern my be formed as a plurality of wiring patterns in a desired arrangement and the guide pattern may be formed as a grid shape.

In the flexible wiring board of the present invention, the guide pattern has guide holes for positioning.

In the flexible wiring board of the present invention, the wiring pattern may comprise projecting electrodes or flat electrodes.

In the flexible wiring board of the present invention, a first wiring pattern is formed on one side of the insulating substrate and a second wiring pattern is formed on the opposite side of the substrate to the first wiring pattern.

In the flexible wiring board of the present invention, the second wiring pattern has projecting electrodes.

In the flexible wiring board of the present invention, the second wiring pattern comprises flat electrodes.

According to the present invention, a reinforcing guide pattern is formed at the same time as a wiring pattern is formed on a copper foil, whereby a flexible wiring board having a wiring pattern integral with a reinforcing guide pattern as described in the foregoing invention, for example, can be obtained only with essential steps for manufacturing the flexible wiring board. As a result, the step of the prior art for bonding a reinforcing guide frame is eliminated, thereby reducing the costs required for manufacturing the flexible wiring board. As used herein, the term “integral” excludes two or more separated items bonded together.

The present invention used the same material for wiring patterns and guide patterns, thereby ensuring rigidity of reinforcing guides and avoiding any difference in thermal distortion between guide patterns and wiring patterns.

As a result, insulating layers can be substantially provided with rigidity by guide patterns and the positions of electrodes in wiring patterns can be maintained without producing wrinkles or other defects in the insulating layers, whereby a flexible wiring board with high handling properties and connection reliability can be obtained.

The present invention can further improve handling properties of flexible wiring boards because reinforcing guides of guide patterns have a height greater than the height of electrodes of wiring patterns so that the electrodes are protected with the reinforcing guides during manufacturing processes or mounting interposers.

Guide patterns here can be formed as a frame shape as defined in the foregoing invention or formed as a grid shape when a plurality of wiring patterns are arranged, whereby handling properties of the resulting flexible wiring boards can be ensured. Especially, a plurality of flexible wiring boards integral with a guide pattern can be obtained at the same teas in the invention described above.

Also according to the present invention, flexible wiring boards can be precisely positioned relative to another wiring board to be connected by means of forming guide holes in reinforcing guides of guide patterns, thereby ensuring high connection reliability as described above and increasing the size of wiring boards connected.

According to the present invention, a wiring pattern having projecting electrodes can be formed and connected to a wiring board having a flat electrodes in contact holes, for example. According to the present invention, a wiring pattern having flat electrodes in contact holes can be formed and connected to a wiring board having projecting electrodes, for example.

As a result, the applicable variation of flexible wiring boards can be expanded, so that they can be connected to various wiring boards having different electrode configurations.

According to the present invention, a wiring pattern can be formed on each side of a flexible wiring board, so that even a multilayer wiring board can be prepared with easy handling and high connection reliability.

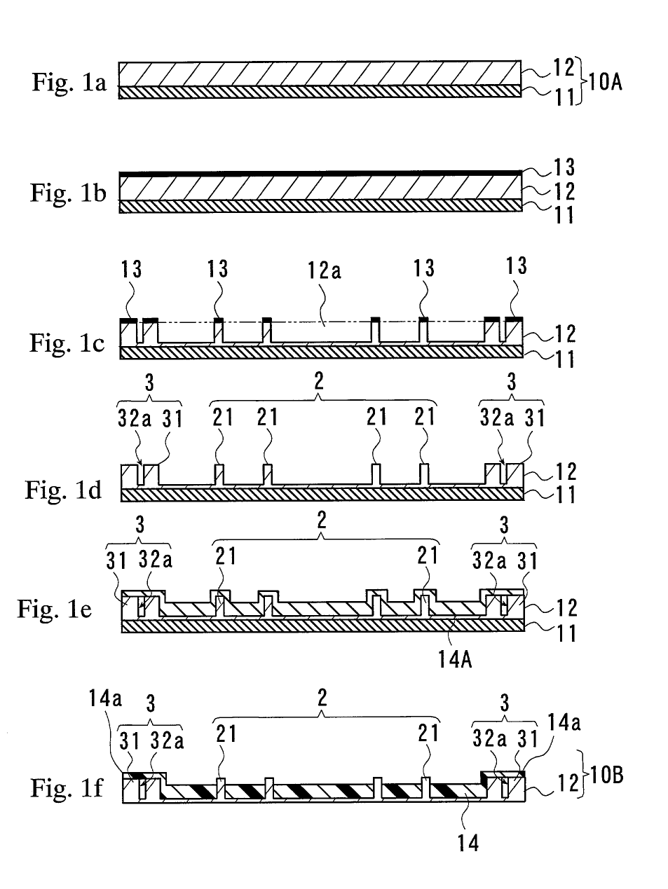

FIGS. 1 (a)-(f) show steps 1-6 of a process for manufacturing a flexible wiring board according to a first embodiment of the present invention.

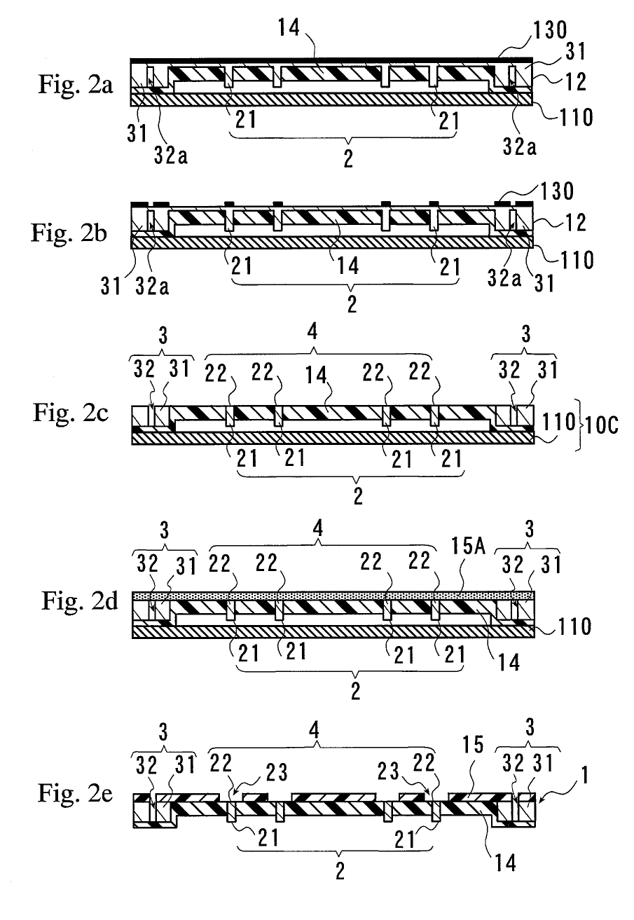

FIGS. 2(a)-(e) Show steps 7-11 of the same process for manufacturing a flexible wiring board.

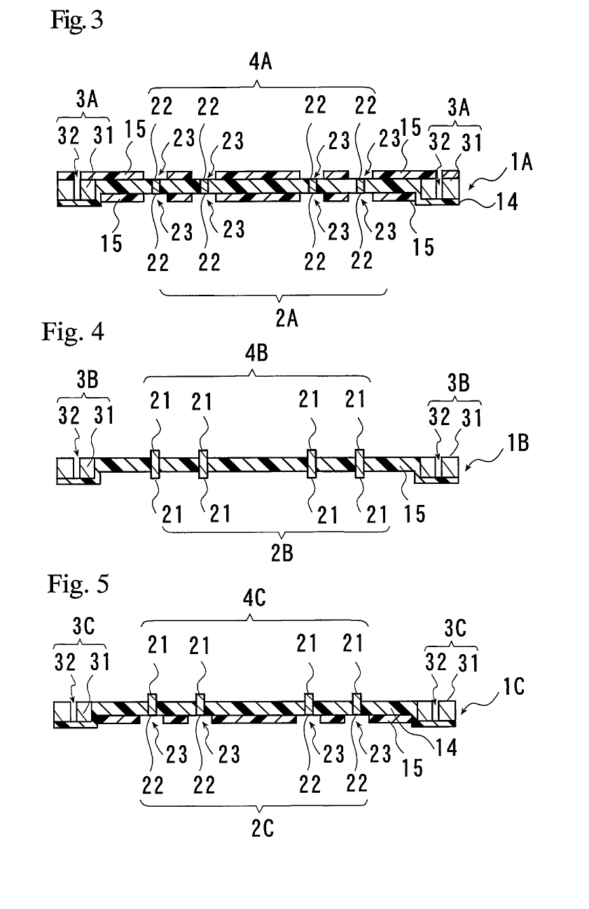

FIG. 3 is a diagram showing a flexible wiring board according to a second embodiment of the present invention.

FIG. 4 is a diagram showing a flexible wiring board according to a third embodiment of the present invention.

FIG. 5 is a diagram showing a flexible wiring board according to a fourth embodiment of the present invention.

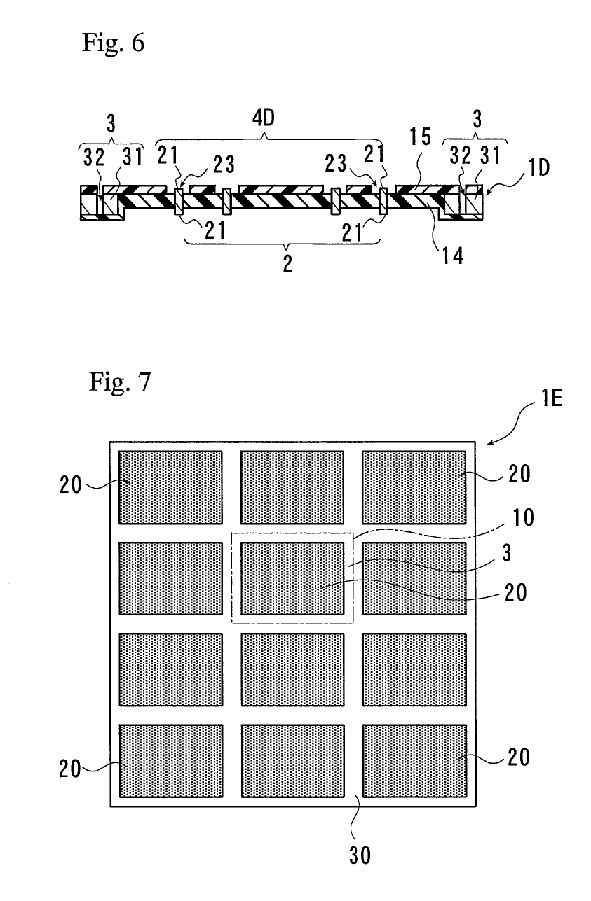

FIG. 6 is a diagram showing a flexible wiring board according to a fifth embodiment of the present invention.

FIG. 7 is a plan view showing a flexible wiring board according to a sixth embodiment of the present invention.

### DETAILED DESCRIPTION OF PREFERRED EMBODIMENTS

Preferred embodiments of processes for manufacturing a flexible wiring board according to the present invention will now be described In detail with reference to the drawings.

FIGS. 1 (a)-(f) show steps 1-6 of a process for manufacturing a flexible wiring board according to a first embodiment of the present invention.

FIG. 2 (a)-(e) show steps 7-11 of the same process for manufacturing a flexible wiring board.

In the present embodiment as shown in FIGS. 1 and 2, a first wiring pattern 2 and a guide pattern 3 are produced in steps 1-6, a second wiring pattern 4 is produced in steps 7-9, and a cover layer 15 is produced in steps 10 and 11.

As shown in FIG. 1 (a), a lamination 10A comprising a rectangular insulating carrier film 11 made of a protective film, for example, and a copper foil (metal foil) 12 having the same shape as that of the carrier film 11 applied thereon is initially prepared at step 1. The thickness of this copper foil 12 is not specifically limited, but preferably 50-70 μm from the viewpoint of adjusting the height of projecting electrodes 21 and reinforcing guide 31 described below.

Then, a dry film 13 made of a photosensitive resist is applied on a copper foil 12 at step 2 as shown in FIG 1 (b).

At step 3, the surface of dry film 13 is exposed to light through a first photomask not shown having a desired pattern and developed to form a resist pattern 13a as shown in FIG. 1 (c).

In the present embodiment, the first photomask preliminary has the same pattern as first wiring pattern 2 to be formed within copper foil 12 and the same pattern as guide pattern 3 to be formed around the outer periphery of copper foil 12 during later steps, and this same pattern as guide pattern 3 includes a plurality of patterns for guide holes 32.

At step 4, an etchant such as ferric chloride is used for etching to remove parts 12a of copper foil 12 other than the resist pattern 13a in a desired depth, as shown in FIG. 1 (c) and (d). Then, the resist pattern 13a is removed.

Thus, a first wiring pattern 2 having projecting electrodes 21 is formed in an inner region on copper foil 12. On the other hand, a guide pattern 3 consisting of a frame shape reinforcing guide 31 is formed around the outer periphery on copper foil 12, and blind guide holes 32a precursory of guide holes 32 are formed in reinforcing guide 31.

At step 5, a polyamic acid solution, a precursor of a polyimide resin, is applied on the entire surface of copper foil 12 having passed step 4 to form a precursor layer 14A, as shown in FIG. 1 (e).

The thickness of precursor layer 14A here is not specifically limited but preferably 10-30 μm after drying from the viewpoint of providing a difference in height between reinforcing guide 31 and projecting electrodes 21 and ensuring Insulation.

For example, an alkali-resistant resist solution is applied on the entire surface of such a precursor layer 14A. Then, the assembly is exposed to light through a mask not shown having the same pattern as first wiring pattern 2 and developed to form an alkali-resistant resist layer not shown at parts of first wiring pattern 2 other than projecting electrode 21.

Then, only precursor layer 14A on each projecting electrode 21 is removed by alkali etching with an etchant such as TMAH to expose the head of each projecting electrode 21.

At step 6, the remaining precursor layer 14A is dated by heating at a temperature of 140-350° C. and then carrier film 11 to removed to give a lamination 10B comprising an insulating film (insulating layer) 14 made of a polyimide resin laminated on copper foil 12, as shown in FIG. 1 (f). In this lamination 10B, reinforcing guide 31 has a height greater than the height of projecting electrodes 21 by the thickness of insulating film 14a.

At step 7, lamination 10B having passed step 6 is inverted to turn upward the side on which projecting electrodes 21 on copper foil 22 are not formed, and the lamination 10A in this state is applied on a carrier film 110 and a dry film 130 similar to dry film 13 used at step 2 is laminated on copper foil 12, as shown in FIG. 2 (a).

At step 8, the surface of dry film 130 is exposed to light through a second photomask not shown having a desired pattern and developed to form a resist patter, as shown in FIG 2 (b).

At step 9, the same etchant as used at step 4 is used for etching to remove parts of copper foil 12 other than the resist pattern, thereby forming a second wiring pattern 4 having flat electrodes 22 on copper foil 12 and through guide holes 32 in copper foil 12 of guide pattern 3, as shown in FIG. 2 (c).

At step 10, a photosensitive resist 15A such as a photosensitive resin is applied on the entire surface of lamination 10C having passed step 9, as shown in FIG. 2 (d).

At step 11, the assembly is exposed to light through a mask having a desired pattern as shown in FIG. 2 (e) to form contact holes 23 having a desired size around electrodes 22 of second wiring pattern 4 and reopen guide holes 32 once closed.

Then, photosensitive resist 15A is cured at a temperature of 130-250° C. to form a cover layer 15 and carrier film 110 is removed to obtain a flexible wiring board 1.

As described above, the present embodiment comprises forming guide pattern 3 at the same time as first wiring pattern 2 is formed on copper foil 12, whereby a flexible wiring board 1 integral with reinforcing guide 31 can be obtained only with essential steps for manufacturing flexible wiring board 1. As a result, the step of the prior art for bonding a reinforcing guide frame is eliminated, thereby reducing the costs required for manufacturing flexible wiring board 1.

The present embodiment preferably uses the same material for first and second wiring pattern 2, 4 and guide pattern 3, thereby ensuring rigidity of reinforcing guide 31 and avoiding any difference in thermal distortion between guide pattern 3 and first and second wiring patterns 2, 4.

As a result, insulating film 14 can be substantially provided with rigidity by reinforcing guide 31 and the positions of electrodes 21, 22 in first and second wiring patterns 2, 4 can be maintained without producing wrinkles or other defects whereby a flexible wiring board 1 with high handling properties and connection reliability can be obtained.

Especially in the present embodiment, flexible wiring board 1 can be precisely positioned relative to another wiring board to be connected by means of guide holes 32 in reinforcing guide 31 of guide pattern 3, whereby even a multilayer wiring board can be produced with easy handling and high connection reliability as described above and the multilayer wiring board can be provided with an increased size.

Moreover, the present embodiment can further improve handling properties of flexible wiring board 1 because reinforcing guide 31 of guide pattern 3 has a height greater than the height of projecting electrodes 21 of first wiring pattern 2 so that projecting electrodes 21 are protected with reinforcing guide 31 during manufacturing processes or mounting interposers, for example.

FIG. 3 is a diagram showing a flexible wiring board according to a second embodiment of the present invention.

As shown in FIG. 3, flexible wiring board 1A of the present embodiment has first and second wiring patterns 2A, 4A and guide pattern 3A similarly to the first embodiment, but differs from the first embodiment in that both first wiring pattern 2A and second wiring pattern 4A have flat electrodes 22 in contact holes 23.

That is, flexible wiring board 1A of the present embodiment is designed to be connected to another wiring board having projecting electrodes via both first and second wiring patterns 2A, 4A in contrast to flexible wiring board 1 of the first embodiment that is designed to be connected to a wiring board having flat electrodes via first wiring pattern 2 and to a wiring board having projecting electrodes via second wiring pattern 4.

Such a first wiring pattern 2A is produced by applying a resist only for guide pattern 3 at step 3 and etching the assembly to remove copper foil 12 at the part of future first wiring pattern 2A in a desired depth. Then, the surface of this copper foil 12 is subjected to steps 7-11 above to give first wiring pattern 2A.

In addition to the first embodiment, the present embodiment expands the applicable variation of flexible wiring boards 1, 1A so that they can be connected to various wiring boards having different electrode configurations. The other structures and advantages are the same as the above described embodiment, and are not further described here.

FIG. 4 this a diagram showing a flexible wiring board according to a third embodiment of the present invention.

As shown in FIG. 4, flexible wiring board 1B of the present embodiment has first and second wiring patterns 2B, 4B and guide pattern 3B similarly to the first embodiment, but differs from the first embodiment in that both first wiring pattern 2B and second wiring pattern 4B have projecting electrodes 21. The other structures and advantages are the same as those of the preceding embodiment and are not further described here.

FIG. 5 is a diagram showing a flexible wiring board according to a fourth embodiment of the present invention.

As shown in FIG. 5, flexible wiring board 1C of the present embodiment has first and second wiring patterns 2C, 4C and guide pattern 3C similarly to the first embodiment, but differs from the first embodiment in that first wiring pattern 2C has flat electrodes 22 in contact holes 23 while second wiring pattern 4C has projecting electrodes 21. The other structures and advantages are the same as those of the preceding embodiments, and are not further described here.

FIG. 6 is a diagram showing a flexible wiring board according to a fifth embodiment of the present invention.

As shown in FIG. 6, flexible wiring board 1D of the present embodiment has first and second wiring patterns 2D, 4D and guide pattern 4D similarly to the first embodiment, but differs from the first embodiment in that second wiring pattern 4D has projecting electrodes 21 in contact holes 23. The other structures and advantages are the same as those of the preceding embodiments, and are not further described here.

FIG. 7, is a plan view showing a flexible wiring board according to a sixth embodiment of the present invention.

As shown in FIG. 7, flexible wiring board 1E of the present embodiment has flexible wiring board components 10 each consisting of a pair of first and second wiring patterns 20 and a frame shape guide pattern 30 surrounding the wiring pattern pair similarly to the preceding embodiments, but differs from the preceding embodiments in that a plurality of wiring pattern pairs 20 are arranged at regular intervals and guide patterns 30 are in the form of a grid filling the intervals therebetween.

According to the present embodiment, a plurality of flexible wiring boards integral with a reinforcing guide can be obtained at the same time.

The present invention is not limited to the foregoing embodiments, but may be modified in various aspects.

For example, the present invention is not limited to the foregoing embodiments in which a guide pattern is formed as a projecting frame shop or grid shape, but also includes structures in which a flexible wiring board can be supported at 3 or more points by using a flat frame or grid provided with a combination of an elongate projection and a point projection or a combination of a pair of elongate projections.

As described above, the present invention provides a process for manufacturing a flexible wiring board with easy handling at reduced production costs.

What is claimed is:

1. A process for manufacturing a flexible wiring board comprising forming a wiring pattern and a reinforcing guide pattern by etching a metal foil on an insulating substrate.

2. A flexible wiring board comprising a wiring pattern formed of a desired metal on a film-like insulating substrate wherein a reinforcing guide pattern having a same material as that of the wiring pattern is formed on the insulating substrate.

3. The flexible wiring board according to claim 2 wherein the guide pattern has a projecting reinforcing guide having a thickness greater than that of the wiring pattern.

4. The flexible wiring board according to claim 2 wherein the guide pattern is formed as a frame shape surrounding the periphery of the wiring pattern.

5. The flexible wiring board according to claim 3 wherein the guide pattern is formed as a frame shape surrounding the periphery of the wiring pattern.

6. The flexible wiring board according to claims 2 wherein the wiring pattern is formed a plurality of wiring patterns in a desired arrangement and the guide pattern is formed as a grid shape.

7. The flexible wiring board according to claim 3 wherein the wiring pattern is formed as a plurality of wiring patterns in a desired arrangement and the guide pattern is formed as a grid shape.

8. The flexible wiring board according to claim 4 wherein the guide pattern has guide holes for positioning.

9. The flexible wiring board according to claim 5 wherein the guide pattern has guide holes for positioning.

10. The flexible wiring board according to claim 6 wherein the guide pattern has guide holes for positioning.

11. The flexible wiring board according to claim 2 wherein the wiring pattern has projecting electrodes.

12. The flexible wiring board according to claim 2 wherein the wiring pattern has projecting electrodes.

13. The flexible wiring board according to claim 2 wherein the wiring pattern has flat electrodes.

14. The flexible wiring board according to claim 2 wherein a first wiring pattern is formed on one side of the insulating substrate, and a second wiring pattern is formed on an opposite side of the insulating substrate to the wiring pattern.

15. The flexible wiring board according to claim 14 wherein the second wiring pattern has projecting electrodes.

16. The flexible wiring board of claim 14 wherein the second wiring pattern has flat electrodes.

17. The flexible wiring board according to claim 2 wherein the reinforcing guide pattern is formed integral with the wiring pattern on the insulating substrate.
